(19) United States
(12) Patent Application Publication
(10) Pub. No.: US 2019/0363303 A1
(43) Pub. Date: Nov. 28, 2019

(54) DISPLAY DEVICE PRODUCTION METHOD, DISPLAY DEVICE PRODUCTION DEVICE, AND INSPECTION DEVICE

(71) Applicant: Sharp Kabushiki Kaisha, Sakai City, Osaka (JP)

(72) Inventors: Mayuko SAKAMOTO, Sakai City (JP); Katsuyuki SUGA, Sakai City (JP)

(21) Appl. No.: 16/067,169

(22) PCT Filed: Mar. 29, 2017
(86) PCT No.: PCT/JP2017/013036

§ 371 Date: Jun. 29, 2018

(51) Int. Cl. H01L 51/56; H01L 51/00; H01L 21/66; H01L 27/32; H05K 3/46; H05K 3/32; H01L 27/12

(52) U.S. Cl. CPC H01L 51/56; H01L 51/0097; H01L 22/12; H01L 27/1262; H05K 3/4626; H05K 3/326; H01L 27/1218; H01L 27/3244

(57) ABSTRACT

A display device production method is a production method in which, after a layered body including a resin layer, a TFT layer, and a light emitting element layer is formed on a substrate that is transparent, a lower face of the resin layer is irradiated with laser from a reverse face of the substrate using a laser peeling device, and the substrate is peeled from the layered body. The display device production method includes measuring an optical characteristic of the substrate that is peeled off, and performing predetermined processing in a case that a measurement result exceeds a threshold value.

### TECHNICAL FIELD

The disclosure is related to a display device production method.

### BACKGROUND ART

When producing a display device that includes EL elements, for example, a layered body including a resin layer, a TFT layer, a light emitting element layer and the like, is formed on a glass substrate, a lower face of the resin layer is irradiated with laser light from a reverse face of the glass substrate and the glass substrate is peeled off, and a film is bonded to the lower face of the resin layer.

### CITATION LIST

### Patent Literature

PTL 1: JP 2004-349543 A (published Dec. 9, 2004)

### SUMMARY

### Technical Problem

In a case where there are variations in the intensity of laser light with which a lower face of a resin layer is irradiated, an amount of carbide occurring on the lower face of the resin layer as a result of the laser irradiation becomes greater, and an adhesion strength of a lower face film may weaken.

### Solution to Problem

A display device production method according to a first aspect of the disclosure is a display device production method in which, after a layered body including a resin layer, a TFT layer, and a light emitting element layer is formed on a substrate that is transparent, a lower face of the resin layer is irradiated with laser from a reverse face of the substrate using a laser peeling device, and the substrate is peeled from the layered body. The display device production method includes measuring an optical characteristic of the substrate that is peeled off, and performing predetermined processing in a case that a measurement result exceeds a threshold value.

### Advantageous Effects of Invention

According to an aspect of the disclosure, an adhesion strength of a lower face film on a display device can be secured.

### BRIEF DESCRIPTION OF DRAWINGS

FIG. 1 is a flowchart illustrating an example of a display device production method.

FIG. 2A is a cross-sectional view illustrating a configuration (a state in which a layered body is formed on a substrate) of the display device during formation, and FIG. 2B is a cross-sectional view illustrating a configuration of the display device.

FIG. 3 is a plan view illustrating the configuration (the state in which the layered body is formed on the substrate) of the display device during formation.

FIG. 4 is a schematic diagram illustrating a method for irradiating a resin layer of the layered body with laser.

FIGS. 5A and 5B are schematic diagrams illustrating a specific example of separating the substrate and the layered body.

FIGS. 6A and 6B are schematic diagrams illustrating a measurement example using an inspection device according to an embodiment.

FIG. 7 is a block diagram illustrating a configuration of a display device production device of the embodiment.

FIG. 8 is a graph showing a relationship between transmittance and laser intensity.

FIG. 9 is a plan view illustrating inspection areas of the substrate according to the embodiment.

FIG. 10 is a plan view illustrating another example of inspection areas of the substrate according to the embodiment.

### DESCRIPTION OF EMBODIMENTS

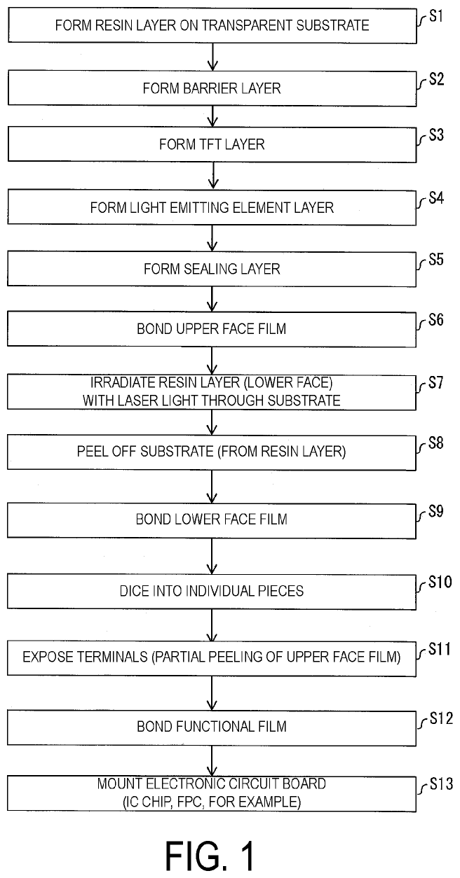

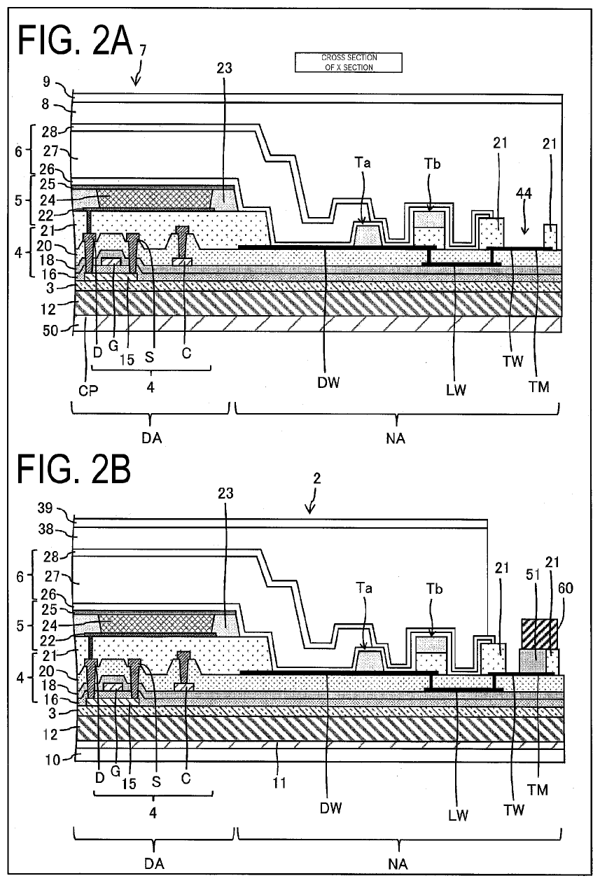

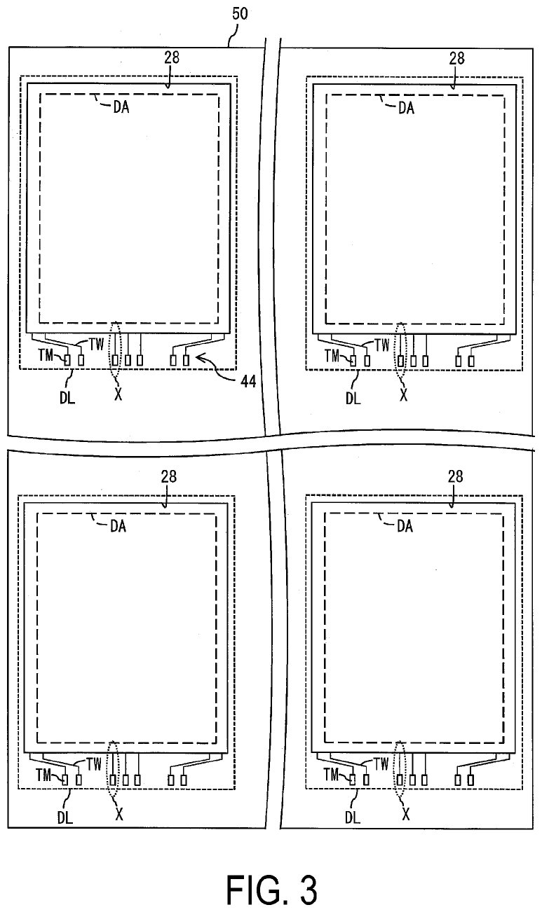

FIG. 1 is a flowchart illustrating an example of a display device production method. FIG. 2A is a cross-sectional view illustrating a configuration (a state in which a layered body is formed on a substrate) of the display device during formation, and FIG. 2B is a cross-sectional view illustrating a configuration of the display device. FIG. 3 is a plan view illustrating the configuration (the state in which the layered body is formed on the substrate) of the display device during formation.

When the flexible display device is produced, as illustrated in FIG. 1, FIG. 2A and FIG. 3, first, a resin layer 12 is formed on a transparent substrate 50 (a mother glass, for example) (step S1). Next, a barrier layer 3 is formed (step S2). Next, a TFT layer 4 is formed (step S3). Next, a light emitting element layer (an OLED layer, for example) 5 is formed (step S4). Next, a sealing layer 6 is formed (step S5). Next, an upper face film 9 (a PET film, for example) is bonded to the sealing layer 6, with an adhesive layer 8 interposed therebetween (step S6).

Next, the lower face of the resin layer 12 is irradiated with a laser beam through the substrate 50 (step S7). Here, the resin layer 12 absorbs the laser beam with which the lower face of the substrate 50 has been irradiated and that has passed through the substrate 50, and as a result, the lower face of the resin layer 12 (an interface with the substrate 50) alters due to ablation, and a bonding strength between the resin layer 12 and the substrate 50 weakens. Next, the substrate 50 is peeled from the resin layer 12 (step S8). Next, as illustrated in FIG. 2B, a lower face film 10 (a PET film, for example) is bonded to the lower face of the resin layer 12, with an adhesive layer 11 interposed therebetween (step S9). Then, a layered body 7 including the lower face film 10, the resin layer 12, the barrier layer 3, the TFT layer 4, the light emitting element layer 5, the sealing layer 6, and the upper face film 9 is divided along cutting lines DL, and a plurality of individual pieces are cut out (step S10). Next, terminal exposure is performed by peeling a part (a section on a terminal portion 44) of the upper face film 9 of the individual piece (step S11). Next, a functional film 39 is bonded to the upper side of the sealing layer 6 of the individual piece, with an adhesive layer 38 interposed therebetween (step S12). Then, an electronic circuit board 60 is mounted onto the terminal portion 44 of the individual piece, with an anisotropic conductive material 51 interposed therebetween (step S13). In this way, a display device 2 illustrated in FIG. 2B is obtained. Note that each of the above steps are performed by a display device production device.

Examples of the material used in the resin layer 12 include a polyimide, an epoxy, or a polyamide. Examples of the material used in the lower face film 10 include polyethylene terephthalate (PET).

The barrier layer 3 is a layer for preventing moisture or impurities from reaching the TFT layer 4 or the light emitting element layer 5 when the display device 2 is used. The barrier layer 3 can be configured, for example, by a silicon oxide film, a silicon nitride film, or a silicon oxynitride film, or by a layered film of these films, formed using CVD.

The TFT layer 4 includes a semiconductor film 15, an inorganic insulating film 16 (a gate insulating film) formed on the semiconductor layer 15, a gate electrode G formed on the gate insulating film 16, an inorganic insulating film 18 formed on the gate electrode G, a capacity wiring line C formed on the inorganic insulating film 18, an inorganic insulating film 20 formed on the capacity wiring line C, a source electrode S and a drain electrode D formed on the inorganic insulating film 20, and a flattening film 21 formed on the source electrode S and the drain electrode D.

A thin film transistor (TFT) is configured to include the semiconductor film 15, the inorganic insulating film 16 (the gate insulating film), and the gate electrode G. The source electrode S is connected to a source region of the semiconductor film 15, and the drain electrode D is connected to a drain region of the semiconductor film 15.

The semiconductor film 15 is formed of low-temperature polysilicon (LTPS) or an oxide semiconductor, for example. The gate insulating film 16 can be configured, for example, by a silicon oxide (SiOx) film, a silicon nitride (SiNx) film, or by a layered film of these films, formed using CVD. The gate electrode G, the source electrode S, the drain electrode D, and the terminals, for example, are configured by a single layer film including a metal such as aluminum (Al), tungsten (W), molybdenum (Mo), tantalum (Ta), chromium (Cr), titanium (Ti), or copper (Cu), or a layered film of these. Note that, in FIGS. 2A and 2B, the TFT is illustrated that has a top gate configuration in which the semiconductor film 15 forms the channel, but the TFT may have a bottom gate configuration (when the TFT channel is the oxide semiconductor, for example).

The inorganic insulating films 18 and 20 can be formed by CVD, for example, and can be configured by a silicon oxide (SiOx) film, a silicon nitride (SiNx) film, or by a layered film of these films. The flattening film (interlayer insulating film) 21 can be formed, for example, of a coatable photosensitive organic material such as a polyimide or an acrylic.

The terminal portion 44 is provided on an end portion (a non-active region NA) of the TFT layer 4. The terminal portion 44 includes a terminal TM that is used for connecting with an IC chip or the electronic circuit board 60 such as an FPC and a terminal wiring line TW that is connected to the terminal TM. The terminal wiring line TW is electrically connected to various wiring lines of the TFT layer 4 with a relay wiring line LW and a lead-out wiring line DW therebetween.

The terminal TM, the terminal wiring line TW, and the lead-out wiring line DW are formed in the same process as the source electrode S, for example, and thus, are formed in the same layer (on the inorganic insulating film 20) and of the same material (two layers of titanium film and an aluminum film sandwiched between the two layers of titanium film, for example) as the source electrode S. The relay wiring line LW is formed in the same process as the capacity electrode C, for example. End faces (edges) of the terminal TM, the terminal wiring line TW, and the lead-out wiring line DW are covered by the flattening film 21.

The light emitting element layer 5 (an organic light emitting diode layer, for example) includes an anode electrode 22 formed on the flattening film 21, a bank 23 that defines a sub pixel of an active region (display region) DA, an electroluminescence (EL) layer 24 formed on the anode electrode 22, and a cathode electrode 25 formed on the EL layer 24, and a light emitting element (an organic light emitting diode (OLED), for example) is configured by the anode electrode 22, the EL layer 24, and the cathode electrode 25.

The EL layer 24 is formed in a region (a sub pixel region) surrounded by the bank 23, by vapor deposition or an ink-jet method. When the light emitting element layer 5 is the organic light emitting diode (OLED) layer, the EL layer 24 is formed, for example, by layering a hole injecting layer, a hole transport layer, a light emitting layer, an electron transport layer, and an electron injecting layer, in this order from a lower layer side.

The anode electrode (positive electrode) 22 is formed by layering Indium Tin Oxide (ITO) and an alloy containing Ag, for example, and has light reflectivity (to be described below in more detail). The cathode electrode 25 can be formed of a transparent electrically conductive material such as Indium Tin Oxide (ITO) and Indium Zinc Oxide (IZO).

When the light emitting element layer 5 is the OLED layer, holes and electrons are recombined inside the EL layer 24 by a drive current between the anode electrode 22 and the cathode electrode 25, and light is emitted as a result of excitons that are generated by the recombination falling into a ground state. Since the cathode electrode 25 is transparent, and the anode electrode 22 is light-reflective, the light emitted from the EL layer 24 travels upwards and results in top emission.

The light emitting element layer 5 is not limited to being configured by the OLED element, and may be configured by an inorganic light emitting diode or a quantum dot light emitting diode.

A protrusion Ta and a protrusion Tb that define edges of an organic sealing film 27 are formed in the non-active region NA. The protrusion Ta functions as a liquid stopper when the organic sealing film 27 is applied using an ink-jet method, and the protrusion Tb functions as a backup liquid stopper. Note that a lower portion of the protrusion Tb is configured by the flattening film 21, and functions as a protection film for an end face of the lead-out wiring line DW. The bank 23, the protrusion Ta, and an upper portion of the protrusion Tb can be formed in the same process, for example, by using a coatable photosensitive organic material such as a polyimide, an epoxy, or an acrylic.

The sealing layer 6 is transparent, and includes a first inorganic sealing film 26 covering the cathode electrode 25, the organic sealing film 27 formed on the first inorganic sealing film 26, and a second inorganic sealing film 28 covering the organic sealing film 27.

The first inorganic sealing film 26 and the second inorganic sealing film 28 can each be configured, for example, by a silicon oxide film, a silicon nitride film, or a silicon oxynitride film, or by a layered film of these, formed using CVD. The organic sealing film 27 is thicker than the first inorganic sealing film 26 and the second inorganic sealing film 28, is a transparent organic film, and can be formed of a coatable photosensitive organic material such as a polyimide or an acrylic. For example, after applying an ink containing such an organic material onto the first inorganic sealing film 26 using the ink-jet method, the ink is cured by UV irradiation. The sealing layer 6 covers the light emitting element layer 5 and inhibits foreign matter, such as water and oxygen, from penetrating the light emitting element layer 5.

Note that the upper face film 9 is bonded onto the sealing layer 6 with the adhesive layer 8 interposed therebetween, and also functions as a support material when the substrate 50 is peeled off. Examples of a material of the upper face film 9 include polyethylene terephthalate (PET).

The lower face film 10 is formed of PET or the like, and, by being bonded to the lower face of the resin layer 12 after the substrate 50 has been peeled off, functions as a support material and a protection material.

The functional film 39 has an optical compensation function, a touch sensor function, a protective function or the like, for example. The electronic circuit board 60 is the IC chip or the flexible printed circuit board (FPC) that is mounted on the plurality of terminals TM, for example.

In a present embodiment, optical characteristics of the substrate 50 that has been peeled off at step S8 in FIG. 1 are measured, and predetermined processing is performed when a measurement result exceeds a threshold value.

### First Embodiment

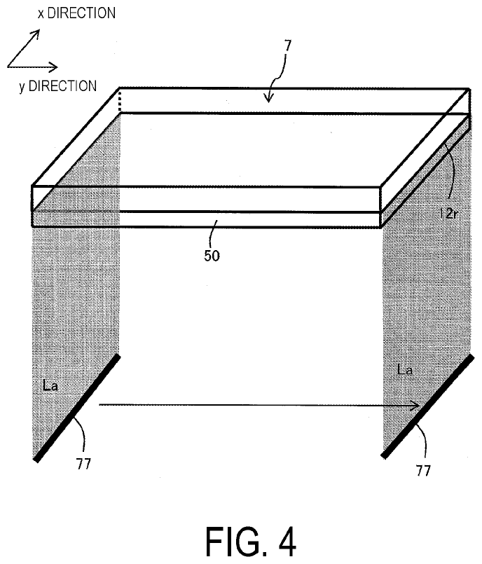

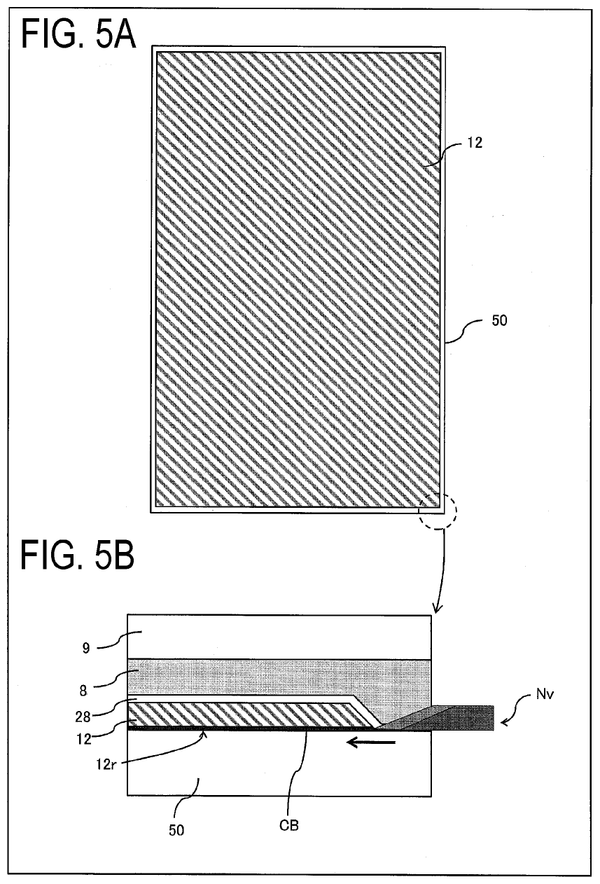

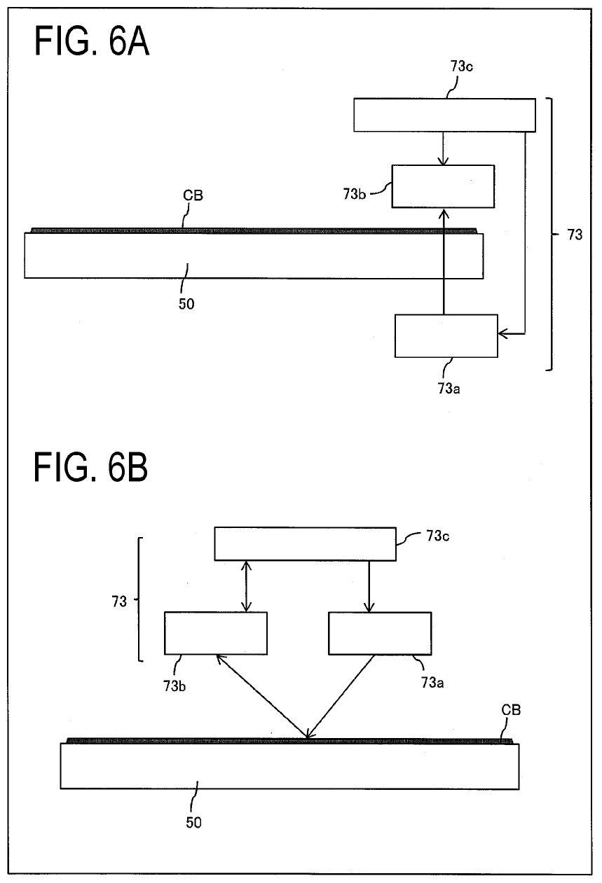

FIG. 4 is a schematic diagram illustrating a method for irradiating the resin layer of the layered body with laser. FIGS. 5A and 5B are schematic diagrams illustrating a specific example of separating the substrate and the layered body. FIGS. 6A and 6B are schematic diagrams illustrating a measurement example using an inspection device according to a first embodiment.

As illustrated in FIGS. 2A to 6B, in the first embodiment, after the layered body 7, which includes the resin layer 12, the TFT layer 4, and the light emitting element layer 5, is formed on the transparent substrate 50, a lower face 12r of the resin layer 12 is irradiated with a laser light La from the reverse face of the substrate 50 using a laser peeling device (to be described later), and, as illustrated in FIG. 5B, a knife Nv is used to separate the resin layer 12 and the substrate 50. Then, an inspection device 73 illustrated in FIGS. 6A and 6B is used to measure the optical characteristics of the peeled off substrate 50, and the predetermined processing is performed when the measurement result exceeds the threshold value.

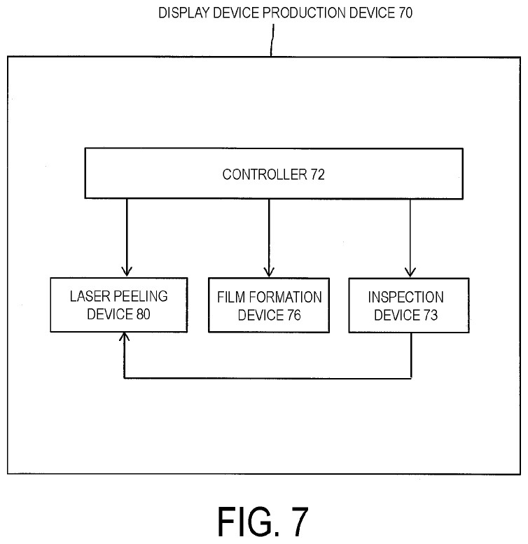

Note that, as illustrated in FIG. 7, a display device production device 70 includes a film formation device 76, a laser peeling device 80 including a laser device 77, the inspection device 73, and a controller 72 configured to control these devices. The laser peeling device 80 configured to receive the control of the controller 72 performs step S7 to step S8 illustrated in FIG. 1.

In FIG. 4, the laser light La emitted by the laser device 77 included in the laser peeling device 80 is a long thin beam that extends in an x direction, and has approximately the same intensity distribution over the x direction. The lower face 12r of the resin layer 12 is scanned with the laser light La from one end to the other end (in a y direction), and thus laser ablation is performed on the lower face 12r of the resin layer 12.

As illustrated in FIGS. 5A and 5B, the resin layer 12, the inorganic sealing film 28, the adhesive layer 8, and the upper face film 9 are layered near the end portion of the substrate 50, and the knife Nv that is inserted from the end face of the layered body 7 is caused to advance underneath the edge of the resin layer 12 on which the laser ablation has been performed, and separate the resin layer 12 and the substrate 50. Note that, a carbide CB is formed on the lower face 12r of the resin layer 12 (the interface with the substrate 50) due to the laser ablation.

In the present embodiment, for example, as illustrated in FIG. 6A, the transmittance of the substrate 50 is measured using the inspection device 73 including a light projecting unit 73a, a light receiving unit 73b, and a control unit 73c configured to control the light projecting unit 73a and the light receiver 73b. More specifically, light is projected from the light projecting unit 73a, from the lower face to the upper face (the face on which the carbide CB is formed) of the substrate 50, and the transmitted light is received by the light receiving unit 73b. The control unit 73c is configured to perform processing in accordance with the transmittance calculated from an amount of light received by the light receiving unit 73b.

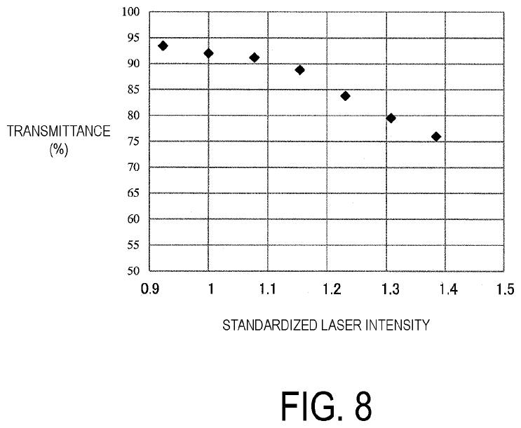

FIG. 8 is a graph showing a relationship between a transmittance and a standardized laser intensity. In FIG. 8, a minimum laser intensity at which substrate peeling is possible is assumed to be 1.0. Here, it can be seen that, as the laser intensity increases, the amount of the carbide CB on the substrate 50 increases and the transmittance of the substrate 50 deteriorates. Furthermore, it can also be seen that, as the amount of the carbide CB on the substrate 50 increases, the amount of the carbide CB remaining on the lower face 12r of the resin layer 12 after being separated from the substrate 50 also increases.

Here, an allowable value (threshold value) of the transmittance is assumed to be 80% and when it falls below 80% (when there is a variation of 30% or greater in the laser intensity), the control unit 73c issues a command to perform abnormality notification to the outside, using an alarm, a display, or the like.

Processing performed by the control unit 73c is not limited to the notification command as described above. For example, the control unit 73c may issue a command to perform a follow-up investigation on the layered body 7 separated from the substrate 50 for which the abnormality (exceeding the threshold value) has been detected, and consequently on the individual piece (display device 2) cut therefrom. In this case, the layered body 7 or the individual piece (display device 2) is determined to be a defective product on the basis of the result of the follow-up investigation.

Furthermore, the control unit 73c may issue a command to stop the laser peeling device 80. In this case, the laser peeling device 80 is inspected to clarify a cause.

In the present embodiment, for example, as illustrated in FIG. 6B, the reflectivity of the substrate 50 may be measured using the inspection device 73 including the light projecting unit 73a, the light receiving unit 73b, and the control unit 73c configured to control the light projecting unit 73a and the light receiving unit 73b. More specifically, light is projected from the light projecting unit 73a toward the upper face (the face on which the carbide CB is formed) of the substrate 50, and the reflected light is received by the light receiving unit 73b. The control unit 73c performs processing in accordance with the reflectivity calculated from an amount of light received by the light receiving unit 73b.

In this way, according to the present embodiment, since the amount of the carbide CB remaining on the lower face 12r of the resin layer 12 can be ascertained using the inspection device 73, the adhesive strength between the lower face film 10 and the resin layer 12 can be secured.

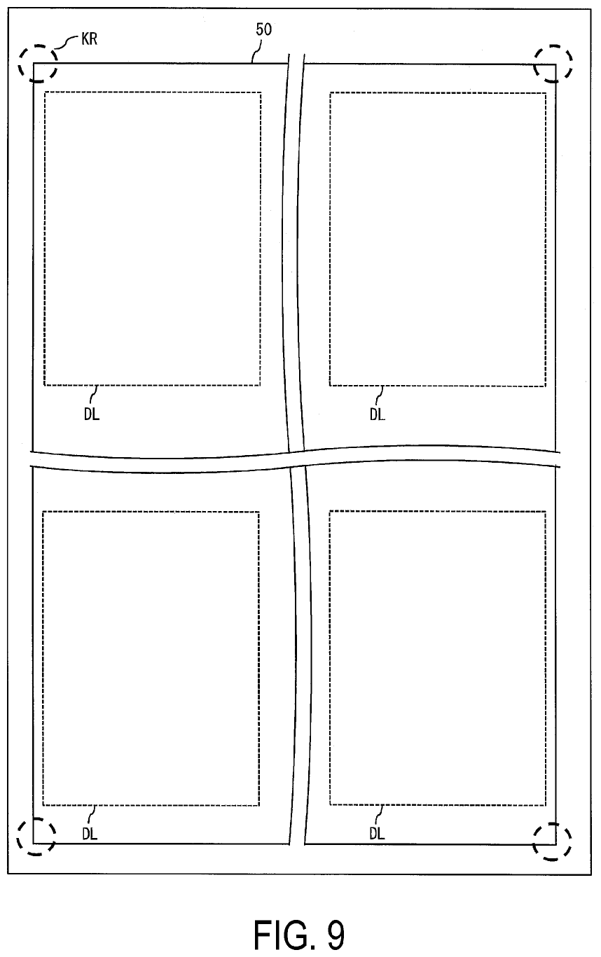

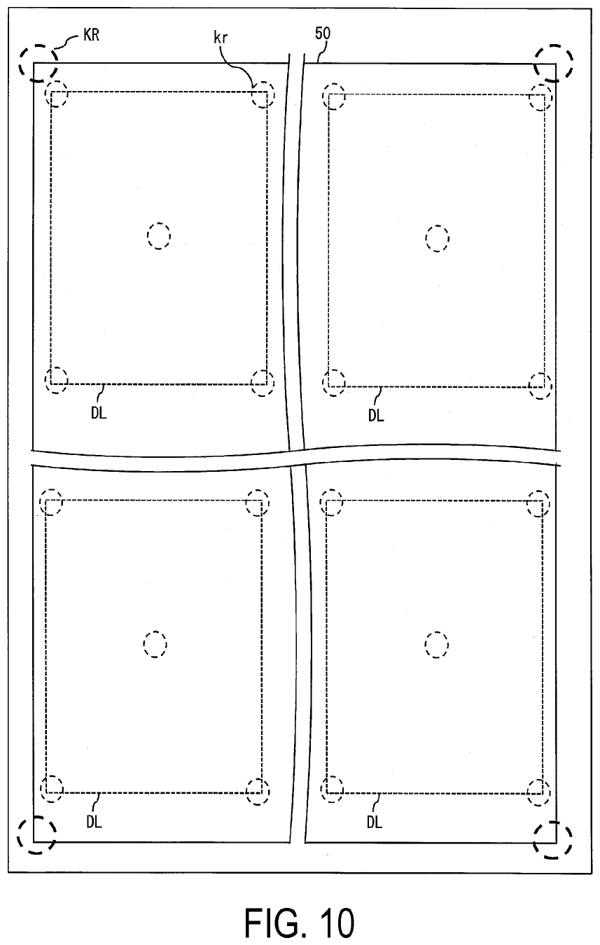

Four corner regions KR (regions on the edges of the resin layer 12) of the substrate 50, as illustrated in FIG. 9, may be used as substrate measurement regions, and, as illustrated in FIG. 10, in addition to the substrate corner regions KR, corner regions kr corresponding to each of the rectangular cutting lines DL may be used as the measurement regions.

An electro-optical element (an electro-optical element whose luminance and transmittance are controlled by an electric current) provided in the display device 2 according to the present embodiment is not particularly limited to a specific element. Examples of the display device 2 according to the present embodiment include an organic Electro Luminescence (EL) display provided with an Organic Light Emitting Diode (OLED) as the electro-optical element, an inorganic EL display provided with an inorganic light emitting diode as the electro-optical element, and a QLED display provided with a Quantum Dot Light Emitting Diode (QLED) as the electro-optical element.

### Supplement

First aspect: In a display device production method in which, after a layered body including a resin layer, a TFT layer, and a light emitting element layer is formed on a substrate that is transparent, a lower face of the resin layer is irradiated with laser from a reverse face of the substrate using a laser peeling device, and the substrate is peeled from the layered body, the display device production method includes measuring an optical characteristic of the substrate that is peeled off, and performing predetermined processing in a case that a measurement result exceeds a threshold value.

Second aspect: In the display device production method according to the first aspect, the optical characteristic is light transmittance.

Third aspect: In the display device production method according to the first aspect, the optical characteristic is light reflectivity.

Fourth aspect: In the display device production method according to any one of the first to third aspects, the predetermined processing includes notifying the outside that the measurement result exceeds the threshold value.

Fifth aspect: In the display device production method according to any one of the first to fourth aspects, the predetermined processing includes performing a follow-up investigation on the layered body.

Sixth aspect: In the display device production method according to any one of the first to fifth aspects, the predetermined processing includes stopping the laser peeling device.

Seventh aspect: In the display device production method according to any one of the first to sixth aspects, at least one corner region of the substrate is measured.

Eighth aspect: In the display device production method according to any one of the first to seventh aspects, a region corresponding to an edge of the resin layer on the substrate is measured.

Ninth aspect: In the display device production method according to any one of the first to eighth aspects, after the substrate has been peeled off, a lower face film is bonded to the lower face of the resin layer, and the layered body and the lower face film are both divided to obtain a plurality of individual pieces.

Tenth aspect: In the display device production method according to the ninth aspect, on the substrate, regions corresponding to each of the plurality of individual pieces are measured.

Eleventh aspect: In the display device production method according to any one of the first to tenth aspects, the resin layer includes a polyimide.

Twelfth aspect: In the display device production method according to any one of the first to eleventh aspects, a carbide remains on the substrate after peeling.

Thirteenth aspect: In the display device production method according to any one of the first to twelfth aspects, the substrate is peeled from the layered body by inserting a knife from an end face of the layered body.

Fourteenth aspect: In a display device production device in which, after a layered body including a resin layer, a TFT layer, and a light emitting element layer is formed on a substrate that is transparent, a lower face of the resin layer is irradiated with laser from a reverse face of the substrate, and the substrate is peeled from the layered body, the display device production device is configured to measure an optical characteristic of the substrate that is peeled off, and to perform predetermined processing in a case that a measurement result exceeds a threshold value.

Fifteenth aspect: An inspection device is configured to measure an optical characteristic of a substrate that is obtained by irradiating a layered body including a resin layer, a TFT layer, and a light emitting element layer formed on the substrate that is transparent with laser, and peeling the substrate from the layered body, and to perform predetermined processing in a case that a measurement result exceeds a threshold value.

The disclosure is not limited to each of the above-described embodiments, and embodiments obtained by appropriately combining technical approaches stated in each of the different embodiments also fall within the scope of the technology of the disclosure. Moreover, novel technical features may be formed by combining the technical approaches stated in each of the embodiments.

### REFERENCE SIGNS LIST

2 Display device

4 TFT layer

5 Light emitting element layer

6 Sealing layer

10 Lower face film

12 Resin layer

21 Flattening film

24 EL layer

44 Terminal portion

50 Substrate

70 Display device production device

76 Film formation device

73 Inspection device

TM Terminal

NA Non-active region

DA Active region

DL Cutting line

1. A display device production method in which, after a layered body including a resin layer, a TFT layer, and a light emitting element layer is formed on a substrate that is transparent, a lower face of the resin layer is irradiated with laser from a reverse face of the substrate using a laser peeling device, and the substrate is peeled from the layered body, the display device production method comprising:
measuring an optical characteristic of the substrate that is peeled off; and
performing predetermined processing in a case that a measurement result exceeds a threshold value.

2. The display device production method according to claim 1,
wherein the optical characteristic is light transmittance.

3. The display device production method according to claim 1,
wherein the optical characteristic is light reflectivity.

4. The display device production method according to claim 1,
wherein the predetermined processing includes notifying the outside that the measurement result exceeds the threshold value.

5. The display device production method according to claim 1,
wherein the predetermined processing includes performing a follow-up investigation on the layered body.

6. The display device production method according to claim 1,
wherein the predetermined processing includes stopping the laser peeling device.

7. The display device production method according to claim 1,
wherein at least one corner region of the substrate is measured.

8. The display device production method according to claim 1,
wherein a region corresponding to an edge of the resin layer on the substrate is measured.

9. The display device production method according to claim 1,
wherein, after the substrate has been peeled off, a lower face film is bonded to the lower face of the resin layer, and the layered body and the lower face film are both divided to obtain a plurality of individual pieces.

10. The display device production method according to claim 9,
wherein, on the substrate, regions corresponding to each of the plurality of individual pieces are measured.

11. The display device production method according to claim 1,
wherein the resin layer includes a polyimide.

12. The display device production method according to claim 1,
wherein a carbide remains on the substrate.

13. The display device production method according to claim 1,
wherein the substrate is peeled from the layered body by inserting a knife from an end face of the layered body.

14. A display device production device in which, after a layered body including a resin layer, a TFT layer, and a light emitting element layer is formed on a substrate that is transparent, a lower face of the resin layer is irradiated with laser from a reverse face of the substrate, and the substrate is peeled from the layered body,
wherein the display device production device is configured to measure an optical characteristic of the substrate that is peeled off, and to perform predetermined processing in a case that a measurement result exceeds a threshold value.

15. (canceled)
